(19) United States
(12) Patent Application Publication
(10) Pub. No.: US 2023/0197727 A1
(43) Pub. Date: Jun. 22, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventor: Guifen YANG, Hefei City (CN)

(73) Assignee: CHANGXIN MEMORY TECHNOLOGIES, INC., Hefei City (CN)

(21) Appl. No.: 18/170,522

(22) Filed: Feb. 16, 2023

Related U.S. Application Data
(63) Continuation of application No. PCT/CN2022/092008, filed on May 10, 2022.

(30) Foreign Application Priority Data
Sep. 3, 2021 (CN) 202111033067.1

(51) Int. Cl. H01L 27/092; H01L 21/8238; H01L 27/02

(52) U.S. Cl. CPC H01L 27/0922; H01L 21/823857; H01L 21/823892; H01L 27/0207

(57) ABSTRACT

A semiconductor structure includes a well area of first conductive type, which includes: a first device area, where a first active area is formed in the first device area, a first device unit is formed in the first active area and configured to provide a first type driving current; and a second device area, connected to the first device area in a length direction of the well area of first conductive type, where a second active area is formed in the second device area, a second device unit is formed in the second active area and configured to provide a second type driving current. A current value of the second type driving current is greater than a current value of the first type driving current. A width of well area of the first device area is the same as a width of well area of the second device area.

### CROSS-REFERENCE TO RELATED APPLICATIONS

This is a continuation of International Patent Application No. PCT/CN2022/092008 filed on May 10, 2022, which claims priority to Chinese Patent Application No. 202111033067.1 filed on Sep. 03, 2021. The disclosures of the above-referenced applications are hereby incorporated by reference in their entirety.

### BACKGROUND

For a semiconductor device such as a Metal Oxide Semiconductor (MOS) transistor, an aspect ratio of a conductive channel thereof is in direct proportion to a driving current that it can provide. That is, the greater the aspect ratio of the conductive channel is, the higher the driving current that the device can provide. The conductive channel is located in an active area in a corresponding well area. Therefore, during designing a semiconductor structure, the width of a well area where a device unit is located is usually set according to the magnitude of the driving current that needs to be provided by the device unit. For the device unit which needs to provide a high driving current, the width of the well area where the device unit is located is usually set to be greater.

However, when such a design manner is adopted, the performance and the yield of products with smaller dimensions are not ideal.

### SUMMARY

The disclosure relates to the technical field of integrated circuits, and in particular, to a semiconductor structure and a method for manufacturing a semiconductor structure.

According to various embodiments of the disclosure, a semiconductor structure and a method for manufacturing a semiconductor structure are provided.

According to various embodiments of the disclosure, a semiconductor structure is provided, which includes a well area of first conductive type. The well area of first conductive type includes: a first device area and a second device area.

The first active area is formed in the first device area. A first device unit is formed in the first active area. The first device unit is configured to provide a first type driving current.

The second device area is connected to the first device area in a length direction of the well area of first conductive type. A second active area is formed in the second device area. A second device unit is formed in the second active area. The second device unit is configured to provide a second type driving current. A current value of the second type driving current is greater than a current value of the first type driving current.

A width of well area of the first device area is the same as a width of well area of the second device area.

According to various embodiments of the disclosure, a method for manufacturing a semiconductor structure is further provided, which includes the following operations.

A substrate is provided.

A well area of first conductive type is formed on the substrate, where the well area of first conductive type includes a first device area and a second device area with a same width of well area.

A first active area is formed in the first device area, and a second active area is formed in the second device area.

A first device unit is formed in the first active area, and a second device unit is formed in the second active area. The first device unit has a first type driving current, and the second device unit has a second type driving current. A current value of the second type driving current is greater than a current value of the first type driving current.

Details of one or more embodiments of the disclosure are set forth in the following drawings and descriptions. Other features, purposes, and advantages of the disclosure will become apparent from the description, drawings, and claims.

### BRIEF DESCRIPTION OF THE DRAWINGS

In order to more clearly illustrate the embodiments of the disclosure or the technical solutions in the related art, the drawings used in the description of the embodiments or the related art will be briefly described below. It is apparent that the drawings in the following description are only some embodiments of the disclosure, and other drawings can be obtained by those skilled in the art according to these drawings without any creative work.

FIG. 1 illustrates a schematic diagram of a semiconductor structure provided by an embodiment.

FIG. 2 illustrates a schematic diagram of a semiconductor structure provided by another embodiment.

FIG. 3 illustrates a schematic diagram of a circuit of a semiconductor structure provided by an embodiment.

FIG. 4 illustrates a flowchart of a method for manufacturing a semiconductor structure provided by an embodiment.

Reference numerals in the drawings: 100-first device unit, 200-second device unit, 210-base device, 220-additional device, 300-third device unit, and 400-fourth device unit.

In order to describe or illustrate the embodiments and/or examples of the disclosures disclosed herein better, reference may be made to one or more of the drawings. The additional details or examples used to describe the drawings should not be considered as limitations to the scope of the disclosed disclosure, the presently described embodiments and/or examples, and any of the presently understood best modes of these disclosures.

### DETAILED DESCRIPTION

In order to facilitate the understanding of the disclosure, the disclosure will be described more comprehensively below with reference to related drawings. Embodiments of the disclosure are shown in the drawings. However, the disclosure may be implemented in many different forms and are not limited to the embodiments described herein. On the contrary, an objective of providing these embodiments is to make the disclosed content of the disclosure more thorough and comprehensive.

Unless otherwise defined, all technical and scientific terms used herein shall have the same meanings as commonly understood by those skilled in the art to which the disclosure belongs. The terms used herein in the specification of the disclosure are only used to describe specific embodiments, and are not intended to limit the disclosure.

It is to be understood that description that an element or layer is “above”, “adjacent to”, “connected to”, or “coupled to” another element or layer may refer to that the element or layer is directly above, adjacent to, connected to or coupled to the another element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers, doping types, and/or parts may be described with terms first, second, third, etc., these elements, components, areas, layers, doping types, and/or parts are not be limited to these terms. These terms are used only to distinguish one element, component, area, layer, doping type, or part from another element, component, area, layer, doping type, or part. Therefore, a first element, component, area, layer, doping type, or part discussed below may be represented as a second element, component, area, layer, or part without departing from the teaching of the disclosure.

As used herein, singular forms “a/an”, “one”, and “the” may also include the plural forms, unless otherwise specified types in the context. It is also understood that the terms “comprising/including”, “having”, etc. specify the existence of the stated features, whole, steps, operations, components, parts or combinations thereof, but do not exclude the possibility of the existence or addition of one or more of the other features, wholes, steps, operations, components, parts or combinations thereof. Meanwhile, in the present specification, terms “and/or” includes any and all combinations of the related listed items.

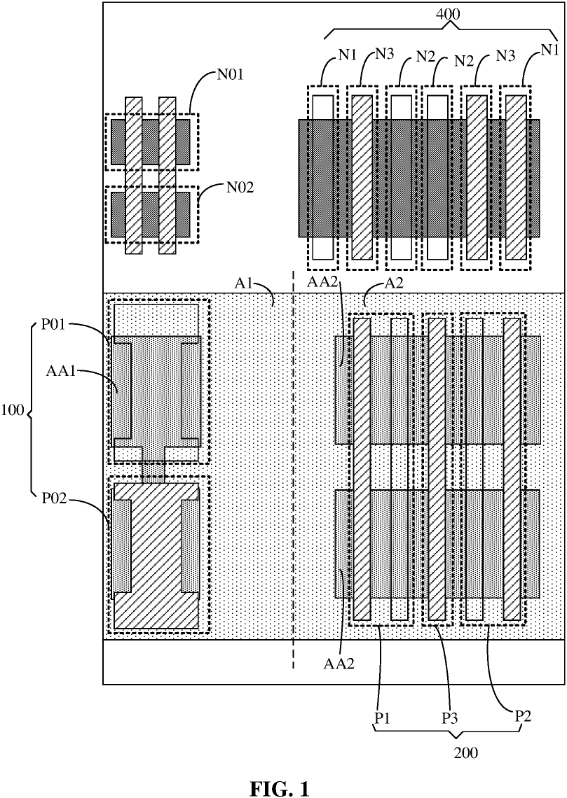

In an embodiment, with reference to FIG. 1, a semiconductor structure is provided, which includes a well area of first conductive type.

The first conductive type may be an N type, or a P type. That is, the well area of first conductive type may be an N-type well area, or a P-type well area.

The well area of first conductive type includes a first device area A1 and a second device area A2. The second device area A2 and the first device area A1 are connected to each other in a length direction of the well area of first conductive type.

A first active area AA1 is formed in the first device area A1. A second active area AA2 is formed in the second device area A2.

After the well area of first conductive type including the first device area A1 and the second device area A2 is formed, a shallow trench isolation structure may be formed in the well area of first conductive type. The shallow trench isolation structure separates the first device area A1 of the well area of first conductive type into the first active area AA1. Further, the shallow trench isolation structure separates the second device area A2 of the well area of first conductive type into the second active area AA2.

It is to be understood that the first active area AA1 may include one or more areas. Similarly, the second active area AA2 may also include one or more areas.

A first device unit 100 is formed in the first active area AA1. The first device unit 100 is configured to provide a first type driving current. A second device unit 200 is formed in the second active area AA2. The second device unit 200 is configured to provide a second type driving current. A current value of the second type driving current is greater than a current value of the first type driving current.

Each of the first device unit 100 and the second device unit 200 may include a plurality of transistors which realize the same function together. As an example, with reference to FIG. 1, each of a first transistor unit P01 and a second transistor unit P02 is the first device unit 100, and includes two transistors arranged in a transverse direction. Each of a fifth transistor unit P1, a sixth transistor unit P2, and a seventh transistor unit P3 is the second device unit 200. The seventh transistor unit P3 includes two transistors arranged in a longitudinal direction. Each of the fifth transistor unit P1 and the sixth transistor unit P2 includes four transistors arranged in two rows and two columns.

Certainly, the first device unit 100 and/or the second device unit 200 may also include only one transistor, which is not limited in the present embodiment.

Further, in the present embodiment, a width of well area of the first device area A1 is the same as a width of well area of the second device area A2, so that the performance and the yield of the semiconductor structure can be effectively improved.

During manufacturing the semiconductor structure, a substrate is provided first. Then, ion implantation is performed on the substrate to form the well area of first conductive type. When a manufacturing process of ion implantation is performed, ions are diffused from the edge of a mask used for implantation, and become dense near an edge of a well so that the doping concentration on a surface of the well varies with the distance from the edge of the mask. Therefore, the doping concentration of the whole well is uneven. This unevenness causes the performance of the device to vary with the distance from the edge of the well, to form a well proximity effect (WPE).

In the present embodiment, the widths of well area of the first device area A1 and the second device area A2 that are connected to each other in a length direction of the well area of first conductive type are the same, so that a step cannot be formed (that is, absent) between the first device area A1 and the second device area A2, thereby effectively reducing the total edge length of the edge of the well, and effectively reducing the impact of the WPE on the performance of the device. Therefore, the present embodiment can effectively improve the performance and the yield of the semiconductor structure.

In an embodiment, transistors in the first device unit 100 and transistors in the second device unit 200 are arranged in rows and columns by taking the length direction of the well area of first conductive type as a row direction. Further, the width of the first active area AA1 is the same as the width of the second active area AA2, so that transistors in the first device unit 100 and transistors in the second device unit 200, which are located in the same row, have the same channel widths, thereby facilitating the design and preparation of the device.

It is to be understood that a source leakage current direction of the transistor is a channel length direction, and a direction perpendicular to the channel length direction is a channel width direction. That is, the channel width direction is consistent with the width direction of the well area of first conductive type.

As an example, with reference to FIG. 1, the first device unit 100 includes a plurality of transistors, and the second device unit 200 includes a plurality of transistors. Further, the plurality of transistors in the first device unit 100 and the plurality of transistors in the second device unit 200 are arranged in a plurality of rows and a plurality of columns.

In this case, the transistors in the first device unit 100 and the transistors in the second device unit 200, which are located in each row, have the same channel widths.

Certainly, each of the first device unit 100 and the second device unit 200 may also include only one transistor. In this case, the transistor in the first device unit 100 and the transistor in the second device unit 200 are located in the same row, and the width of the conductive channel of the transistor in the first device unit 100 and are the same as the width of the conductive channel of the transistor in the second device unit 200.

In an embodiment, a threshold voltage of each of the plurality of transistors in the second device unit 200 is less than a threshold voltage of each of the plurality of transistors in the first device unit 100.

For a transistor device, the lower the threshold voltage thereof is, the higher the corresponding drain current thereof is, that is, the driving current that the device can provide is higher. Therefore, in the present embodiment, the second device unit 200 can provide a second type driving current with a greater current value through the setting of the threshold voltage.

In an embodiment, the doping concentration of the second device area A2 is less than the doping concentration of the first device area A1, so that the doping concentration of the second active area AA2 formed in the second device area A2 is less than the doping concentration of the first active area AA1 formed in the first device area A1.

Further, the second device unit 200 is formed in the second active area AA2, and the first device unit 100 is formed in the first active area AA1. Therefore, in this case, the doping concentration of the conductive channel of each of the plurality of transistors in the second device unit 200 may be less than the doping concentration of the conductive channel of each of the plurality of transistors in the first device unit 100.

The lower the doping concentration of the conductive channel of a transistor device is, the lower the threshold voltage of the device is.

Therefore, according to the present embodiment, by designing the doping concentration of the second device area A2 and the doping concentration of the first device area A1, it may be conveniently and effectively achieved that the threshold voltage of each of the plurality of transistors in the second device unit 200 is less than the threshold voltage of each of the plurality of transistors in the first device unit 100.

As an example, when the ion implantation is performed, the dose of ions implanted into the second device area A2 may be less than the dose of ions implanted into the first device area A1, so that the doping concentration of the second device area A2 is less than the doping concentration of the first device area A1.

In an embodiment, the thickness of a gate dielectric layer of each of the plurality of transistors in the second device unit 200 is less than the thickness of a gate dielectric layer of each of the plurality of transistors in the first device unit 100.

The greater the thickness of the gate dielectric layer of the transistor device is, the higher the threshold voltage of the device is. Therefore, it may be effectively achieved that the threshold voltage of each of the plurality of transistors in the second device unit 200 is less than the threshold voltage of each of the plurality of transistors in the first device unit 100 through the thickness of the gate dielectric layer.

As an example, a gate dielectric layer with less thickness may be deposited in the second device area A2, and a gate dielectric layer with greater thickness may be deposited in the first device area A1.

In an embodiment, the difference between the work function of a gate of each of the plurality of transistors in the second device unit 200 and the work function of the second active area AA2 is less than the difference between the work function of a gate of each of the plurality of transistors in the first device unit 100 and the work function of the first active area AA1.

The different the differences between the work function of the gate and the work function of the active area, the different the threshold voltages of the device. Generally, the smaller the difference between the work functions, the lower the threshold voltage is.

Therefore, it may be effectively achieved that the threshold voltage of each of the plurality of transistors in the second device unit 200 is less than the threshold voltage of each of the plurality of transistors in the first device unit 100 through the difference between the work functions.

As an example, the first active area AA1 and the second active area AA2 may have the same work function, and the gate of each of the plurality of transistors in the second device unit 200 and the gate of each of the plurality of transistors in the first device unit 100 select the materials with different work functions.

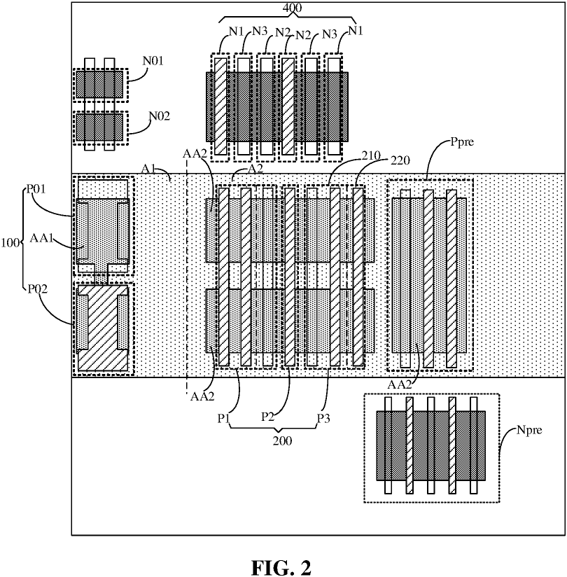

In one embodiment, with reference to FIG. 2, the second device unit 200 includes a base device 210 and an additional device 220. The additional device 220 is a device which is formed in the second device area A2 with the same width of well area as the first device area A1 where the first device unit 100 is located and which is added to provide a higher driving current.

As an example, with reference to FIG. 2, one or more transistors may be added to a fifth transistor unit P1 and a seventh transistor unit P3 in the second device area A2 as an additional device 220. The structures and the dimensions of the added transistors are the same as the structures and the dimensions of the plurality of transistors in the fifth transistor unit P1 and the plurality of transistors in the seventh transistor unit P3 are the same, and the added transistors and the original transistors share a source or drain.

In a conventional process, if the driving current that the second device unit 200 needs to provide is high, the channel width of each of the plurality of transistors in the second device unit 200 may usually be increased accordingly, resulting in a greater width of the well area where the second device unit 200 is located, and the formation of a step between the first device area A1 and the second device area A2.

In the present embodiment, the second device unit 200 has a greater driving current by adding the additional device 220. Further, the width of well area of the second device area A2 where the second device unit 200 is located is set to be the same as the width of well area of the first device area A1 where the first device unit 100 is located, thereby ensuring sufficient driving current demand and effectively reducing the impact of the WPE on the performance of a device.

In an embodiment, the semiconductor structure includes a sense amplifier and a switch control circuit (SWC). The sense amplifier includes the first device unit 100, and the SWC includes the second device unit 200.

Further, the SWC is connected to the sense amplifier through a data signal line, to provide a signal for the sense amplifier.

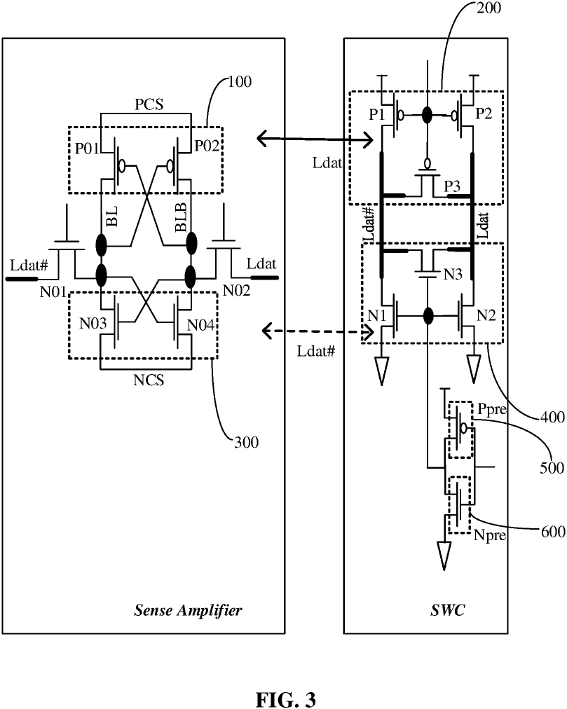

In an embodiment, with reference to FIG. 3, the first device unit 100 includes a first transistor unit P01 and a second transistor unit P02. The first transistor unit P01 and the second transistor unit P02 form two first device units 100. Further, the sense amplifier further includes a third device unit 300. The third device unit 300 includes a third transistor unit N03 and a fourth transistor unit N04. The third transistor unit N03 and the fourth transistor unit N04 form two third device units 300.

The third transistor unit N03 and the first transistor unit P01 form a phase inverter. The gates of the third transistor unit N03 and the first transistor unit P01 are connected to each other, and the drains of the third transistor unit N03 and the first transistor unit P01 are connected to each other. Further, a source of the third transistor unit N03 is connected to a low level signal end, so that a low level signal is input when the third transistor unit N03 is turned on. A source of the first transistor unit P01 is connected to a high level signal end, so that a high level signal is input when the first transistor unit P01 is turned on.

The fourth transistor unit N04 and the second transistor unit P02 form a phase inverter. The gates of the fourth transistor unit N04 and the second transistor unit P02 are connected to each other, and the drains of the fourth transistor unit N04 and the second transistor unit P02 are connected to each other. Further, a source of the fourth transistor unit N04 is connected to a low level signal end, so that a low level signal is input when the fourth transistor unit N04 is turned on. A source of the second transistor unit P02 is connected to a high level signal end, so that a high level signal is input when the second transistor unit P02 is turned on.

Further, the gates of the fourth transistor unit N04 and the second transistor unit P02 are connected to the drains of the third transistor unit N03 and the first transistor unit P01. The drains of the fourth transistor unit N04 and the second transistor unit P02 are connected to the gates of the third transistor unit N03 and the first transistor unit P01. Therefore, when the gates of the fourth transistor unit N04 and the second transistor unit P02 are connected to a low level sense signal, the second transistor unit P02 is turned on, to output a high level signal to the drain of the second transistor unit P02 (that is, the gates of the third transistor unit N03 and the first transistor unit P01) to turn on the third transistor unit N03. The third transistor unit N03 outputs a low level signal to the drain of the third transistor unit N03 (that is, the gates of the fourth transistor unit N04 and the second transistor unit P02) to turn on the second transistor unit P02 again. The above operations are cycled, so that the voltage on a side of the gates of the fourth transistor unit N04 and the second transistor unit P02 (that is, the drains of the third transistor unit N03 and the first transistor unit P01) is lower and lower, while the voltage on a side of the gates of the third transistor unit N03 and the first transistor unit P01 (that is, the drains of the fourth transistor unit N04 and the second transistor unit P02) is higher and higher, thereby effectively amplifying the sense signal.

In one embodiment, with reference to FIG. 3, the data signal line includes a first data line Ldat# and a second data line Ldat. The second device unit 200 includes a fifth transistor unit P1, a sixth transistor unit P2, and a seventh transistor unit P3. The fifth transistor unit P1, the sixth transistor unit P2, and the seventh transistor unit P3 form three second device units 200.

The side of the gates of the fourth transistor unit N04 and the second transistor unit P02 (that is, the drains of the third transistor unit N03 and the first transistor unit P01) is marked as side A, and the side of the gates of the third transistor unit N03 and the first transistor unit P01 (that is, the drains of the fourth transistor unit N04 and the second transistor unit P02) is marked as side B.

A drain of the fifth transistor unit P1 is connected to the first data line Ldat#, and a drain of the sixth transistor unit P2 is connected to the second data line Ldat, so that the SWC may be respectively connected to side A and side B of the sense amplifier through the first data line Ldat# and the second data line Ldat respectively. Sources of the fifth transistor unit P1 and the sixth transistor unit P2 are connected to the same voltage, so that equal potential voltages are pre-charged into side A and side B of the sense amplifier through the first data line Ldat# and the second data line Ldat, thereby ensuring the accuracy of detection.

A source of the seventh transistor unit P3 is connected to the first data line Ldat#, and a drain of the seventh transistor unit P3 is connected to the second data line Ldat, to equalize the pre-charge voltages, thereby further ensuring the accuracy of detection.

In an embodiment, with reference to FIG. 3, the SWC may further include a fourth device unit 400. The fourth device unit 400 includes a eighth transistor unit N1, a ninth transistor unit N2, and a tenth transistor unit N3. The eighth transistor unit N1, the ninth transistor unit N2, and the tenth transistor unit N3 form three fourth device units 400.

A drain of the eighth transistor unit N1 is connected to the first data line Ldat#, and a drain of the ninth transistor unit N2 is connected to the second data line Ldat, so that the SWC may be respectively connected to side A and side B of the sense amplifier through the first data line Ldat# and the second data line Ldat respectively. Sources of the eighth transistor unit N1 the ninth transistor unit N2 are connected to the same voltage, so that equal potential voltages are pre-charged into side A and side B of the sense amplifier through the first data line Ldat# and the second data line Ldat, thereby ensuring the accuracy of detection.

A source of the tenth transistor unit N3 is connected to the first data line Ldat#, and a drain of the tenth transistor unit N3 is connected to the second data line Ldat, to equalize the pre-charge voltages, thereby further ensuring the accuracy of detection.

As an example, the sense amplifier may further include a transistor unit N01 and a transistor unit N02. One end of the transistor unit N01 may be connected to the first data line Ldat#, and another end of the transistor unit N01 may be connected to the side A of the sense amplifier (that is, the side of the gates of the fourth transistor unit N04 and the second transistor unit P02 (that is, the drains of the third transistor unit N03 and the first transistor unit P01)); and further, one end of the transistor unit N02 may be connected to the second data line Ldat, and another end of the transistor unit N02 may be connected to the side B of the sense amplifier (that is, the side of the gates of the third transistor unit N03 and the first transistor unit P01 (that is, the drains of the fourth transistor unit N04 and the second transistor unit P02)), to control a pre-charge signal to be input to the side A and the side B of the sense amplifier through the transistor unit N01 and the transistor unit N02 before the sense signal is input. After the pre-charge is completed, the transistor unit N01 and the transistor unit N02 may be turned off, and then the sense signal is input.

In an embodiment, with reference to FIG. 3, the SWC further includes a P-type switch unit 500 and an N-type switch unit 600.

The P-type switch unit 500 is configured to turn on the fourth device unit 400. The N-type switch unit 600 is configured to turn on the second device unit 200.

With reference to FIG. 3, the P-type switch unit 500 may include a transistor unit Ppre, and the N-type switch unit 600 may include a transistor unit Npre. Drains of the P-type switch unit 500 and the N-type switch unit 600 may be connected to each other, may be connected to gates of various transistors in the second device unit 200, and connected to gates of various transistors in the fourth device unit 400. Further, the gates of the P-type switch unit 500 and the N-type switch unit 600 may be connected to each other, to be controlled through the same gate voltage signal. A source of the P-type switch unit 500 is connected to a high level signal end. A source of the N-type switch unit 600 is connected to a low level signal end.

When a low level gate voltage signal is input, the P-type switch unit 500 is turned on, so that a source high level signal thereof is input to the fourth device unit 400, to turn on the fourth device unit 400. When a high level gate voltage signal is input, the N-type switch unit 600 is turned on, so that a source low level signal thereof is input to the second device unit 200, to turn on the second device unit 200.

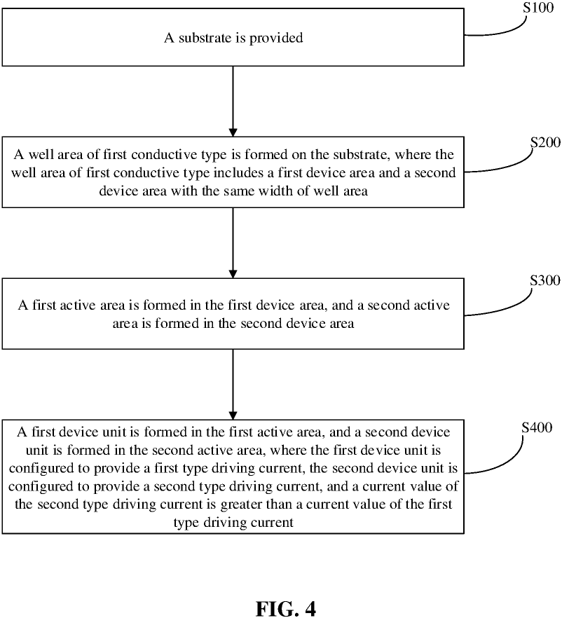

In an embodiment, with reference to FIG. 4, a method for manufacturing a semiconductor structure is also provided, which includes the following operations.

At S100, a substrate is provided.

At S200, a well area of first conductive type is formed on the substrate, where the well area of first conductive type includes a first device area and a second device area with the same width of well area.

At S300, a first active area is formed in the first device area, and a second active area is formed in the second device area.

At S400, a first device unit is formed in the first active area, and a second device unit is formed in the second active area, where the first device unit is configured to provide a first type driving current, the second device unit is configured to provide a second type driving current, and a current value of the second type driving current is greater than a current value of the first type driving current.

In an embodiment, the length direction of the well area of first conductive type is a row direction. Transistors in the first device unit and transistors in the second device unit are arranged in rows and columns. The transistors of the first device unit and the transistors of the second device unit, which are located in the same row, have the same channel widths.

In an embodiment, a threshold voltage of each of the plurality of transistors in the second device unit is less than a threshold voltage of each of the plurality of transistors in the first device unit.

In an embodiment, the doping concentration of the second device area is less than the doping concentration of the first device area.

In an embodiment, S400 includes the following steps.

At S410, a first gate dielectric layer is formed on the first device area, and a second gate dielectric layer is formed on the second device area.

At S420, a first gate is formed on the first gate dielectric layer, and a second gate is formed on the second gate dielectric layer.

In an embodiment, the thickness of the second gate dielectric layer is less than the thickness of the first gate dielectric layer.

In an embodiment, the difference between the work function of the second gate and the work function of the second active area is less than the difference between the work function of the first gate and the work function of the first active area.

In an embodiment, the second device unit includes a base device and an additional device. The additional device is coupled with the base device in parallel.

Specific definition of the method for manufacturing the semiconductor structure may refer to the definition of the semiconductor structure above, which will not be elaborated herein.

It is to be understood that, although various operations in the flowchart of FIG. 4 are shown in order as indicated by the arrows, these operations are not necessarily executed sequentially in the order indicated by the arrows. Unless explicitly stated herein, there is no strict order restriction on the execution of these operations, and these operations may be executed in other orders. In addition, at least part of the operations in FIG. 4 may include a plurality of operations or a plurality of stages. These operations or stages are not necessarily completed at the same time, but may be executed at different times. These operations or stages are not necessarily executed in order, but may be executed in turn or alternately with other operations or at least part of the operations or stages of other operations.

In the description of the present specification, the description of referring of the terms “some embodiments”, “other embodiments”, “ideal embodiments” and the like means that the specific features, structures, materials or features described in combination with this embodiment or example are included in at least one embodiment or example of the disclosure. In the present specification, the schematic descriptions of the abovementioned terms do not necessarily mean the same embodiment or example.

Various technical features of the abovementioned embodiments may be arbitrarily combined with each other. For the sake of brevity of description, all possible combinations of the technical features the abovementioned embodiments are not described. However, as long as there is no contradiction between the combinations of these technical features, all should be considered as the scope of this specification.

The above embodiments are merely illustrative of several implementation manners of the disclosure with specific and detailed description, and are not to be construed as limitations to the patent scope of the present application. It is to be noted that a number of variations and modifications may be made by those of ordinary skill in the art without departing from the conception of the disclosure, and all of these belong to the scope of protection of the disclosure. Therefore, the scope of protection of the patent of disclosure should be determined by the appended claims.

What is claimed is:

1. A semiconductor structure, comprising a well area of first conductive type, wherein the well area of first conductive type comprises:
a first device area, wherein a first active area is formed in the first device area, a first device unit being formed in the first active area, and the first device unit being configured to provide a first type driving current; and
a second device area, wherein the second device area is connected to the first device area in a length direction of the well area of first conductive type, a second active area being formed in the second device area, a second device unit being formed in the second active area, and the second device unit being configured to provide a second type driving current, wherein a current value of the second type driving current is greater than a current value of the first type driving current;
wherein a width of well area of the first device area is the same as a width of well area of the second device area.

2. The semiconductor structure of claim 1, wherein the length direction of the well area of first conductive type is a row direction; a plurality of transistors in the first device unit and a plurality of transistors in the second device unit are arranged in rows and columns; and a width of the first active area is the same as a width of the second active area.

3. The semiconductor structure of claim 2, wherein a threshold voltage of each of the plurality of transistors in the second device unit is less than a threshold voltage of each of the plurality of transistors in the first device unit.

4. The semiconductor structure of claim 3, wherein
a doping concentration of the second device area is less than a doping concentration of the first device area.

5. The semiconductor structure of claim 3, wherein
a thickness of a gate dielectric layer of each of the plurality of transistors in the second device unit is less than a thickness of a gate dielectric layer of each of the plurality of transistors in the first device unit.

6. The semiconductor structure of claim 3, wherein
a difference between a work function of a gate of each of the plurality of transistors in the second device unit and a work function of the second active area is less than a difference between a work function of a gate of each of the plurality of transistors in the first device unit and a work function of the first active area.

7. The semiconductor structure of claim 1, wherein the second device unit comprises a base device and an additional device, and the additional device is coupled with the base device in parallel.

8. The semiconductor structure of claim 1, comprising a sense amplifier and a switch control circuit, wherein the sense amplifier comprises the first device unit; the switch control circuit is connected to the sense amplifier through a data signal line; and the switch control circuit comprises the second device unit.

9. The semiconductor structure of claim 8, wherein
the first device unit comprises a first transistor unit and a second transistor unit;
the sense amplifier further comprises a third device unit, and the third device unit comprises a third transistor unit and a fourth transistor unit;
the third transistor unit and the first transistor unit form a phase inverter, the fourth transistor unit and the second transistor unit form a phase inverter, gates of the fourth transistor unit and the second transistor unit are connected to drains of the third transistor unit and the first transistor unit, and drains of the fourth transistor unit and the second transistor unit are connected to gates of the third transistor unit and the first transistor unit.

10. The semiconductor structure of claim 8, wherein
the second device unit comprises a fifth transistor unit, a sixth transistor unit, and a seventh transistor unit;
the data signal line comprises a first data line and a second data line;
a drain of the fifth transistor unit is connected to the first data line, a drain of the sixth transistor unit is connected to the second data line, a source of the seventh transistor unit is connected to the first data line, and a drain of the seventh transistor unit P3 is connected to the second data line.

11. The semiconductor structure of claim 10, wherein
the switch control circuit further comprises a fourth device unit, and the fourth device unit comprises a eighth transistor unit, a ninth transistor unit and a tenth transistor unit;
a drain of the eighth transistor unit is connected to the first data line, a drain of the ninth transistor unit is connected to the second data line, a source of the tenth transistor unit is connected to the first data line, and a drain of the tenth transistor unit is connected to the second data line.

12. The semiconductor structure of claim 11, wherein the switch control circuit further comprises a P-type switch unit and an N-type switch unit; the P-type switch unit is configured to turn on the fourth device unit, and the N-type switch unit is configured to turn on the second device unit.

13. A method for manufacturing a semiconductor structure, comprising:
providing a substrate;
forming a well area of first conductive type on the substrate, wherein the well area of first conductive type comprises a first device area and a second device area with a same width of well area;
forming a first active area in the first device area, and forming a second active area in the second device area; and
forming a first device unit in the first active area, and forming a second device unit in the second active area, wherein the first device unit has a first type driving current, the second device unit has a second type driving current, and a current value of the second type driving current is greater than a current value of the first type driving current.

14. The method for manufacturing the semiconductor structure of claim 13, wherein a length direction of the well area of first conductive type is a row direction; a plurality of transistors in the first device unit and a plurality of transistors in the second device unit are arranged in rows and columns; and a width of the first active area is the same as a width of the second active area.

15. The method for manufacturing the semiconductor structure of claim 13, wherein a threshold voltage of each of the plurality of transistors in the second device unit is less than a threshold voltage of the plurality of transistor in the first device unit.

16. The method for manufacturing the semiconductor structure of claim 15, wherein a doping concentration of the second device area is less than a doping concentration of the first device area.

17. The method for manufacturing the semiconductor structure of claim 15, wherein
the forming the first device unit in the first active area, and forming the second device unit in the second active area comprises:
forming a first gate dielectric layer on the first device area, and forming a second gate dielectric layer on the second device area; and
forming a first gate on the first gate dielectric layer, and forming a second gate on the second gate dielectric layer.

18. The method for manufacturing the semiconductor structure of claim 17, wherein
a thickness of the second gate dielectric layer is less than a thickness of the first gate dielectric layer.

19. The method for manufacturing the semiconductor structure of claim 17, wherein
a difference between a work function of the second gate and a work function of the second active area is less than a difference between a work function of the first gate and a work function of the first active area.

20. The method for manufacturing the semiconductor structure of claim 13, wherein the second device unit comprises a base device and an additional device, and the additional device is coupled with the base device in parallel.
